(19) United States
(12) Patent Application Publication
(10) Pub. No.: US 2005/0233494 A1
(43) Pub. Date: Oct. 20, 2005

(54) Image sensor and method for fabricating the same

(76) Inventor: Hee Jeong Hong, Chungcheongbuk-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/072,767

(22) Filed: Mar. 3, 2005

(30) Foreign Application Priority Data
Mar. 31, 2004 (KR) 2004-22253

(51) Int. Cl. H01L 21/00

(52) U.S. Cl. 438/57

(57) ABSTRACT

Disclosed is a complementary metal oxide semiconductor (CMOS) image sensor applied by an N-channel stop layer and a method for fabricating the same. The image sensor includes: a P-type semiconductor substrate including an active region provided with a field oxide layer and a pixel region provided with a photodiode region, a native N-channel metal oxide semiconductor (NMOS) transistor region and a normal NMOS transistor region; an N-channel stop layer including a wide width in a horizontal direction and formed around the field oxide layer; and a P-type well formed in a low depth on the P-type semiconductor substrate of the normal NMOS transistor region.

### FIELD OF THE INVENTION

The present invention relates to an image sensor and a method for fabricating the same; and more particularly, to a complementary metal oxide semiconductor (CMOS) image sensor applied by an N-channel stop layer and a method for fabricating the same.

### DESCRIPTION OF RELATED ARTS

In general, a complementary metal oxide semiconductor (CMOS) image sensor is a semiconductor device that converts an optical image to an electrical signal. The CMOS image sensor includes a photo sensitive region capable of sensing a light and a logic circuit region capable of treating the sensed light by using the electrical signal and making a data. Also, the CMOS image sensor adopts a switching method for detecting output sequentially by making and using as many metal oxide semiconductor (MOS) transistors as the number of pixels based on CMOS technology.

FIG. 1 is a circuit diagram illustrating a unit pixel of a conventional CMOS image sensor. As shown in FIG. 1, the unit pixel is provided with one photodiode (PD) which is a photodetector and four transistors (Tx, Rx, Dx and Sx). The four transistors includes a transfer transistor (Tx) for transferring photo-generated charges collected by the PD to a floating node (FD), a reset transistor (Rx) for resetting by outputting charges stored in the FD, a drive transistor (Dx) for operating as a source flower buffer amplifier and a select transistor (Sx) for serving roles in switching and addressing. Furthermore, a plurality of capacitances (Cp and Cf) are existed in the PD and the FD, respectively. There forms a road transistor outside of the unit pixel to read an outputting signal. Hereinafter, a photodiode and a floating node will be explained as a PD and a FD, respectively.

FIG. 2 is a cross-sectional view illustrating a conventional CMOS image sensor. As shown in FIG. 2, a field oxide layer 14 is formed on a P-type substrate provided with a pixel region including a PD, a native N-channel metal oxide semiconductor (NMOS) transistor and a normal NMOS transistor, thereby defining an active region. An N-channel stop layer 13A is formed around the field oxide layer 14 and on a surface of the substrate 10 of the active region. A mini P-type well 15 is formed inside of the substrate of the normal NMOS transistor region and a blanket ion implantation layer 16 is formed inside of the substrate of all transistor regions. A plurality of gates of a transfer transistor (Tx) 18A and a reset transistor (Rx) 18B are formed on an upper portion of the substrate 10 of the native NMOS transistor region. Herein, the Tx 18A and the Rx 18B include a plurality of spacers 22 on lateral sides of each transistor and a plurality of gate insulation layers 17 beneath each transistor. Also, a plurality of gates of a drive transistor (Dx) 18C and a select transistor (Sx) 18D are formed on an upper portion of the substrate 10 of the normal NMOS transistor region. Herein, the Dx and the Sx include a plurality of spacers 22 on lateral sides of each transistor and a plurality of gate insulation layers 17 beneath each transistor. A junction region provided with a plurality of halo regions 23A and 23B, a lightly doped drain (LDD) region 24 and an N⁺-type impurities region 25 is formed in each transistor region. The N⁺-type impurities region 25 formed between the plurality of gates of the Tx and the Rx 18A and 18B is operated as a FD. Furthermore, a PD provided with a depletion layer 19, a deep N⁻-type impurities region 20 and a P⁰-type impurities region 21 is formed inside of the substrate of the PD region.

Herein, the N-channel stop layer 13A described in FIG. 2 is formed to improve a dark property of an image sensor and an electric property of the native NMOS transistor. Typically, as shown in FIG. 3, the N-channel stop layer 13A is formed by performing a vertical ion implantation 13 of an N-channel stop ion originated from boron (B) or boron difluoride (BF₂) with use of an N-channel stop mask for opening only the pixel region after formation of a trench. At this time, an ion implanting energy is set up as much as the N-channel stop ion can transmit to a nitride layer 12 by considering a punch-through property of the native NMOS transistor. Furthermore, a blanket ion implanting layer 16 is typically made of B ion in order to prevent the punch-through property of the plurality of transistors from degradation.

However, if the N-channel stop layer 13A is formed by using these methods, the N-channel stop layer 13A exists even on a lower portion of the gate of the Tx 18A. Accordingly, the N-channel stop layer 13A becomes a factor that disturbs the FD playing a role in transferring a charge from the PD, thereby degrading efficiency on transferring the charge.

Furthermore, the blanket ion implantation layer 16 is formed inside of the deep N⁻-type impurities region 20 of the PD, thereby inducing ions to cancel each other. Accordingly, not only saturation property and sensitivity property are degraded but also a depletion region is decreased by deeply forming the mini P-type well 15 inside of the substrate of the Dx and the Sx. Therefore, the saturation property is much more degraded.

### SUMMARY OF THE INVENTION

It is, therefore, an object of the present invention to provide an image sensor and a method for fabricating the same capable of increasing an efficiency on transferring charges of a transfer transistor (Tx), and of improving a saturation property of a drive transistor (Dx) and a select transistor (Sx).

In accordance with one aspect of the present invention, there is provided an image sensor, including: a P-type semiconductor substrate including an active region provided with a field oxide layer and a pixel region provided with a photodiode region, a native N-channel metal oxide semiconductor (NMOS) transistor region and a normal NMOS transistor region; an N-channel stop layer including a wide width in a horizontal direction and formed around the field oxide layer; and a P-type well formed in a low depth on the P-type semiconductor substrate of the normal NMOS transistor region.

In accordance with another aspect of the present invention, there is provided a method for fabricating an image sensor, including the steps of: forming a mask pattern exposing a predetermined portion of a substrate on a P-type semiconductor substrate defining a pixel region provided with a photodiode region, a native NMOS transistor region and a normal NMOS transistor region; forming a trench in a predetermined thickness by etching the exposed substrate; forming an N-channel stop layer with a wide width in a horizontal direction around the trench by ion implantation an N-channel stop ion in a predetermined tilted angle along with a low energy; forming a field oxide layer by filling an oxide layer in the trench; removing the mask pattern; and forming a P-type well in a low depth on the substrate of the normal NMOS transistor region.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a circuit diagram illustrating a unit pixel of a conventional complementary oxide metal semiconductor (CMOS) image sensor;

FIG. 2 is a cross-sectional view illustrating a conventional CMOS image sensor;

FIG. 3 is a cross-sectional view illustrating a method for fabricating an N-channel stop layer in a conventional CMOS image sensor;

FIG. 4 is a cross-sectional view illustrating a CMOS image sensor in accordance with the present invention; and

FIG. 5 is a cross-sectional view illustrating a method for fabricating an N-channel stop layer in a CMOS image sensor in accordance with the present invention.

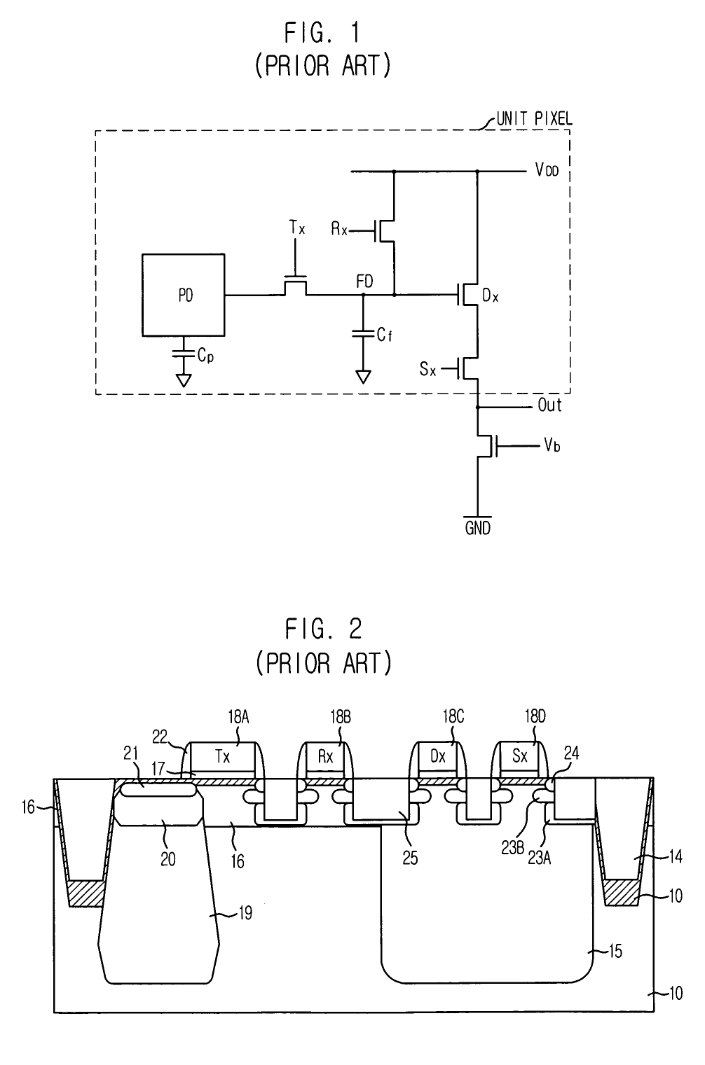

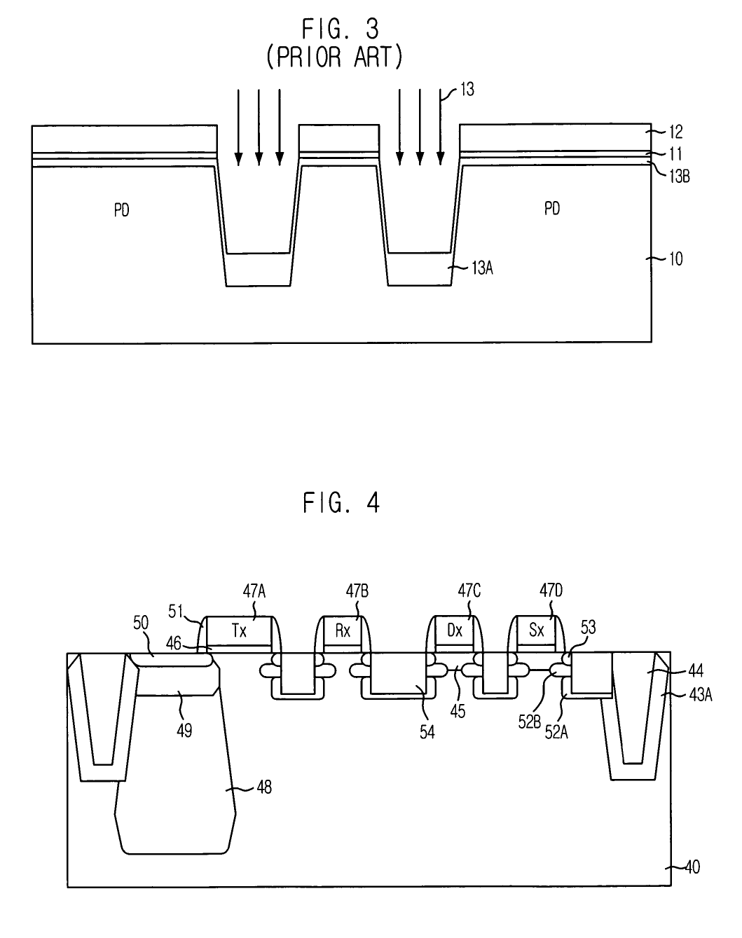

### DETAILED DESCRIPTION OF THE INVENTION

Hereinafter, detailed descriptions on preferred embodiments of the present invention will be provided with reference to the accompanying drawings.

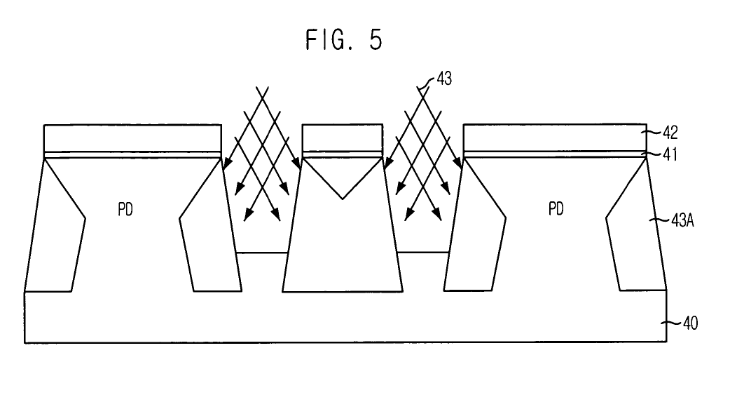

With reference to FIGS. 4 and 5, a method for fabricating a complementary metal oxide semiconductor (CMOS) image sensor in accordance with the preferred embodiments of the present invention is explained.

Referring to FIGS. 4 and 5, a P-type substrate 40 is provided with a pixel region including a photodiode (PD), a native N-channel metal oxide semiconductor transistor and a normal NMOS transistor region. A pad oxide layer 41 with a size ranging from approximately 50 Å to approximately 200 Å and a nitride layer 42 with a size ranging from approximately 1,000 Å to approximately 2,000 Å are sequentially deposited on the P-type substrate 40. Afterwards, the pad oxide layer 41 and the nitride layer 42 are patterned to expose a predetermined portion of the substrate 40 and then, the exposed substrate is etched in a thickness ranging from approximately 3,000 Å to approximately 6,000 Å, thereby forming a trench.

Afterwards, an N-channel stop ion is ion implanted 43 by using an N-channel stop mask opening only pixel region, thereby forming an N-channel stop layer 43A having a relatively wide width in a horizontal direction. At this time, the ion implantation 43 is performed with use of energy as low as not to transmit to the nitride layer 42 in a predetermined tilted angle. Accordingly, it is preferable that the ion implantation 43 is performed in four different directions, e.g., upward, downward, right and left directions, by using B ion along with an energy raging from approximately 10 KeV to approximately 30 KeV, a dose ranging from approximately 1×10¹² ions/cm² to approximately 5×10¹³ ions/cm² for each direction and a tilted angle raging from approximately 15° to approximately 50°.

Afterwards, an oxide layer is deposited on the substrate in a thickness ranging from approximately 4,000 Å to approximately 7,000 Å to bury the trench. Next, a surface of the oxide layer is planarized by employing a chemical mechanical polishing (CMP) process and then, the pad oxide layer 41 and the nitride layer 42 are removed. Thus, a field oxide layer 44 having a shallow trench isolation (STI) structure is formed, thereby defining an active region.

Thereafter, a mini P-type well 45 is formed on the surface of the substrate 40 of the normal NMOS transistor region in a relatively low depth by employing an ion implantation with use of a mask for opening the normal NMOS transistor region of the pixel region with a relatively low energy. It is preferable that the ion implantation should be performed by using B ion along with an energy ranging from approximately 10 KeV to approximately 50 KeV in a dose ranging from approximately 1×10¹¹ ions/cm² to approximately 5×10¹³ ions/cm². Herein, there is another possibility that the mini P-type well 45 is not formed on the surface of the substrate 40 of the normal NMOS transistor region.

Next, a blanket ion implantation process is omitted and a plurality of gates 47A, 47B, 47C and 47D are formed on upper portions of the substrate of each transistor region. Herein, each of the plurality of gates includes a plurality of spacers 51 on lateral side of the gates and a plurality of gate insulation layers 46 beneath each of the transistors. As shown, the plurality of gates of a transfer transistor (Tx) 47A and a reset transistor (Rx) 47B are formed in the native NMOS transistor region, respectively and the plurality of gates of a drive transistor (Dx) 47C and a select transistor (Sx) 47D are formed in the normal NMOS transistor region, respectively.

Afterwards, a photodiode PD including a depletion layer 48, a deep N⁻-type impurities region 49 and a P⁰-type impurities region 50 is formed inside of the substrate 40 of the PD region. A junction region formed with a plurality of halo regions 52A and 52B, a lightly doped drain (LDD) region 53 and an N⁺-type impurities region 54 is formed each transistor region of the pixel region. Herein, the N⁺-type impurities region formed between the plurality of gates of the Tx 47A and the Rx 47B is operated as a floating node (FD).

In accordance with the preferred embodied example, the N-channel stop layer is formed around a field oxide layer 44 in a relatively wide width, thereby preventing degradation of an efficiency on transferring charges. Accordingly, not only a deadzone property of a low light level image can be improved but also, a transistor of a low threshold voltage can be produces.

Furthermore, an insulation property between the PD and each transistor is strengthened due to the N-channel stop layer, thereby not only improving a poor dark condition but also, reducing a leakage current of the transistor.

In addition, the image sensor in accordance with the present invention is formed by omitting the blanket ion implantation process and reducing the mini P-type well region. Therefore, it is possible to expand the depletion regions of the Dx and the Sx, thereby increasing a saturation and a sensitivity properties.

The present invention improves the saturation property of the Dx and the Sx as well as efficiency on transferring charges of the Tx. Thus, it is possible to improve a photo property such as the low light level and the photosensitivity property of the image sensor.

The present application contains subject matter related to the Korean patent application No. KR 2004-0022253, filed in the Korean Patent Office on Mar. 31, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

1. An image sensor, comprising:
a P-type semiconductor substrate including an active region provided with a field oxide layer and a pixel region provided with a photodiode region, a native N-channel metal oxide semiconductor (NMOS) transistor region and a normal NMOS transistor region;
an N-channel stop layer including a wide width in a horizontal direction and formed around the field oxide layer; and
a P-type well formed in a low depth on the P-type semiconductor substrate of the normal NMOS transistor region.

2. A method for fabricating an image sensor, comprising the steps of:
forming a mask pattern exposing a predetermined portion of a substrate on a P-type semiconductor substrate defining a pixel region provided with a photodiode region, a native NMOS transistor region and a normal NMOS transistor region;
forming a trench in a predetermined thickness by etching the exposed substrate;
forming an N-channel stop layer with a wide width in a horizontal direction around the trench by ion implantation an N-channel stop ion in a predetermined tilted angle along with a low energy;
forming a field oxide layer by filling an oxide layer in the trench;
removing the mask pattern; and
forming a P-type well in a low depth on the substrate of the normal NMOS transistor region.

3. The method of claim 2, wherein at the step of forming the N-channel stop layer, the ion implantation is performed in four different directions by using boron ions along with an energy ranging from approximately 10 KeV to approximately 30 KeV, a dose ranging from approximately 1×10¹² ions/cm² to approximately 5×10¹³ ions/cm² for each direction and a tilted angle ranging from approximately 15° to approximately 50°.

4. The method of claim 2, wherein the P-type well is formed by performing an ion implantation with use of boron ions along with an energy raging from approximately 10 KeV to approximately 50 KeV and a dose ranging from approximately 1×10¹¹ ions/cm² to approximately 5×10¹³ ions/cm².
